(19) United States
(12) Patent Application Publication
(10) Pub. No.: US 2014/0186988 A1
(43) Pub. Date: Jul. 3, 2014

(54) CHEMICAL BATH DEPOSITION APPARATUS, METHOD OF FORMING BUFFER LAYER AND METHOD OF MANUFACTURING PHOTOELECTRIC CONVERSION DEVICE

(71) Applicant: FUJIFILM Corporation, Tokyo (JP)

(72) Inventors: Tetsuo KAWANO, Ashigarakami-gun (JP); Hiroshi ARAI, Ashigarakami-gun (JP)

(73) Assignee: FUJIFILM Corporation, Tokyo (JP)

(21) Appl. No.: 14/196,338

(22) Filed: Mar. 4, 2014

Related U.S. Application Data
(63) Continuation of application No. PCT/JP2012/073002, filed on Sep. 3, 2012.

(30) Foreign Application Priority Data
Sep. 5, 2011 (JP) 2011-192896
Sep. 5, 2011 (JP) 2011-192897
Jul. 31, 2012 (JP) 2012-169379

(51) Int. Cl. H01L 31/18

(52) U.S. Cl. CPC H01L 31/18
USPC 438/64; 118/64

(57) ABSTRACT

A chemical bath deposition apparatus includes: a reaction vessel for containing a reaction solution for chemical bath deposition to form a film on a surface of a substrate; a substrate holding section for holding the substrate such that at least the surface of the substrate contacts the reaction solution, the substrate holding section including a fixing surface made of stainless steel on which a back side of the substrate is closely fixed; a heater disposed at a rear side of the fixing surface, the heater heating the substrate from the back side of the substrate; and a reaction solution temperature control unit for controlling temperature of the reaction solution in the reaction vessel.

### TECHNICAL FIELD

The present invention relates to a chemical bath deposition apparatus for use in forming a buffer layer of a photoelectric conversion device, or the like.

The present invention also relates to a method of forming a buffer layer of a photoelectric conversion device using a chemical bath deposition process, and a method of manufacturing a photoelectric conversion device.

### BACKGROUND ART

Photoelectric conversion devices, which include a photoelectric conversion layer and electrodes electrically connected with the photoelectric conversion layer, are used in applications, such as solar batteries. The main stream of conventional solar batteries has been Si solar batteries, which use bulk single-crystal Si or polycrystal Si, or thin-film amorphous Si. On the other hand, compound semiconductor solar batteries, which do not depend on Si, are now being researched and developed. As the compound semiconductor solar batteries, those of a bulk type, such as GaAs solar batteries, etc., and those of a thin-film type, such as CIS or CIGS solar batteries, which contain a group Ib element, a group IIIb element and a group VIb element, are known. CI(G)S is a compound semiconductor represented by the general formula below:

Cu_{1-z}In₁₋ₓGaₓSe_{2-y}S_{y} (wherein 0≦x≦1,0≦y≦2,0≦z≦1)

and it is a CIS semiconductor when x=0 or a CIGS semiconductor when x>0. The CIS and CIGS are collectively described herein as “CI(G)S”.

Conventional thin-film type photoelectric conversion devices, such as CI(G)S photoelectric conversion devices, typically include a buffer layer (a Cd compound, such as CdS, or a Zn compound, such as Zn(O,OH,S)) between the photoelectric conversion layer and a transparent conductive layer (transparent electrode) which is formed above the photoelectric conversion layer. The buffer layer in such a system is usually formed by a chemical bath deposition (CBD) process.

Functions of the buffer layer may include (1) prevention of recombination of photogenerated carriers, (2) control of band discontinuity, (3) lattice matching, (4) coverage of surface unevenness of the photoelectric conversion layer, etc. With respect to the CI(G)S photoelectric conversion devices, etc., which have relatively large surface unevenness of the photoelectric conversion layer, a CBD (Chemical Bath Deposition) process, which is a liquid phase process, may preferably be used to satisfy the condition (4) above.

In the CBD process, the buffer layer is formed on the photoelectric conversion layer typically by immersing a substrate, which has the photoelectric conversion layer formed on the surface thereof, in a reaction solution heated to a predetermined temperature.

However, the CBD process has problems, such that particles (colloid) are formed in the reaction solution at the same time when the buffer layer is deposited on the photoelectric conversion layer, and the particles adhere to the surface on which the buffer layer is formed, and that it is difficult to achieve cost reduction and mass productivity is low because the reaction solution cannot be used repeatedly. It should be noted that, if a buffer layer with such particles adhering to the surface on which the buffer layer is formed is used to form a photoelectric conversion device, the resulting photoelectric conversion device may have degraded performance.

Japanese Unexamined Patent Publication No. 7(1995)-240385 (hereinafter, “Patent Document 1”) has disclosed a method and an apparatus for forming CdS, which allows mass production of CdS. Specifically, Patent Document 1 has proposed a method for forming a CdS film, wherein the temperature of a substrate holder is set to a temperature at which CdS forms on a substrate (for example, 60° C.), and the temperature of a solution is maintained at a temperature at which no CdS forming reaction occurs (40° C. or less). Patent Document 1 teaches that this allows continuous film formation without CdS forming at areas other than the substrate.

Japanese Unexamined Patent Publication No. 2009-259938 (hereinafter, “Patent Document 2”) has disclosed a film forming method, which achieves cost reduction by reducing the used amount of a material solution. Specifically, Patent Document 2 has proposed an apparatus, wherein a necessary amount of solution is dripped on a surface of a substrate and a holding section holding the substrate is heated. Patent Document 2 teaches that this allows reduction of the used amount of the solution and highly accurate control of the substrate temperature distribution, thereby providing a process that can provide a film having good film thickness distribution and film quality distribution while reducing a film formation time.

U.S. Patent Application Publication No. 20110027938 (hereinafter, “Patent Document 3”) has proposed a method wherein a holding section holding a substrate is heated without heating a reaction solution and teaches that this suppresses formation of particles in a reaction solution.

### DISCLOSURE OF INVENTION

According to the CBD processes and apparatuses disclosed in Patent Documents 1 to 3, the formation of particles in the reaction solution can be suppressed, thereby reducing adhesion of the particles to the surface on which the buffer layer is formed. This is also believed to allow repeated use of the reaction solution, thereby allowing cost reduction and mass production.

For practical application, however, there is a need for an apparatus that can form a higher quality buffer layer to provide a photoelectric conversion device having higher photoelectric conversion efficiency.

On the other hand, with respect to manufacturing of photoelectric conversion devices, the buffer layer forming process using the CBD process determines the production rate. Therefore, there is a need for reducing production time of the buffer layer forming process.

In view of the above-described circumstances, the present invention is directed to providing a practical chemical bath deposition apparatus, which can achieve cost reduction by suppressing formation of particles in a reaction solution, and can achieve a higher quality buffer layer.

The present invention is, also directed to providing a method of forming a buffer layer using a CBD process, which can achieve cost reduction by suppressing formation of particles in a reaction solution, and can achieve time reduction of a buffer layer forming process.

An aspect of the chemical bath deposition apparatus of the invention includes: a reaction vessel for containing a reaction solution for chemical bath deposition to form a film on a surface of a substrate; a substrate holding section for holding the substrate such that at least the surface of the substrate contacts the reaction solution, the substrate holding section including a fixing surface made of stainless steel or titanium on which a back side of the substrate is closely fixed; a heater disposed at a rear side of the fixing surface, the heater heating the substrate from the back side of the substrate; and a reaction solution temperature control unit for controlling temperature of the reaction solution in the reaction vessel.

The heater may preferably be a sheet heater disposed across an area larger than an area of the fixing surface where the substrate is fixed.

The heater may particularly preferably be a rubber heater.

The substrate holding section may preferably hold the substrate such the surface of the substrate is oriented in a vertically downward direction (i.e., the surface of the substrate faces the bottom surface of the reaction vessel). In this case, it may be particularly preferable that the fixing surface of the substrate holding section is a semi-cylindrical surface.

Alternatively, the substrate holding section may preferably hold the substrate such that the surface of the substrate is inclined from the vertically downward direction.

Further alternatively, the substrate holding section may hold the substrate parallel to a side wall surface of the reaction vessel.

The substrate holding section may preferably include an end face protective member for preventing a side end face of the substrate fixed on the fixing surface from contacting the reaction solution.

It may be desirable that at least an area of an inner wall of the reaction vessel contacting the reaction solution is coated with a hydrophobic material.

An aspect of the method of forming a buffer layer of the invention is a method of forming a buffer layer of a photoelectric conversion device having a layered structure formed on a substrate, the layered structure including a lower electrode, a photoelectric conversion semiconductor layer, the buffer layer and a transparent conductive layer, the method using an apparatus including: a reaction vessel containing a reaction solution for chemical bath deposition to form the buffer layer; a substrate holding section for holding the substrate having the photoelectric conversion semiconductor layer formed thereon such that at least a surface of the photoelectric conversion semiconductor layer contacts the reaction solution; a heater for heating the substrate; and a reaction solution temperature control unit for controlling temperature of the reaction solution, the method including: mounting the substrate having the photoelectric conversion semiconductor layer forming an outermost surface thereof on the substrate holding section; heating the substrate by the heater to a temperature T₁ [° C.]; starting formation of the buffer layer by bringing at least the surface of the photoelectric conversion semiconductor layer into contact with the reaction solution, the temperature of the reaction solution being controlled to a temperature T₂ [° C.] lower than the temperature T₁, while the substrate is kept heated; and maintaining the substrate at the temperature T₁ and the reaction solution at the temperature T₂ during formation of the buffer layer.

The description “maintaining the substrate at the temperature T₁ and the reaction solution at the temperature T₂” means that temperatures set at the heater and the reaction solution temperature control unit are maintained at the temperatures T₁, T₂, respectively. For example, the actual temperatures of the substrate and the reaction solution may change immediately after the substrate is brought into contact with the reaction solution. The heater and the reaction solution temperature control unit function to bring these temperatures to T₁, T₂ (close to T₁, T₂), respectively.

In particular, in a case where the buffer layer is a Zn compound layer, it may be preferable that the temperatures T₁ [° C.] and T₂ [° C.] satisfy the relationship below:

T₁≧70≧T₂+30.

The Zn compound is one of ZnS, Zn(S,O) and Zn(S,O,OH).

An aspect of the method of manufacturing a photoelectric conversion device of the invention is a method of manufacturing a photoelectric conversion device having a layered structure formed on a substrate, the layered structure including a lower electrode, a photoelectric conversion semiconductor layer, a buffer layer and a transparent conductive layer, the method comprising: forming the buffer layer by the method of forming a buffer layer of the invention.

The chemical bath deposition apparatus of the invention includes the heater for heating the substrate from the back side thereof and the reaction solution temperature control unit for controlling the reaction solution temperature which are independent from each other, so that the substrate temperature and the reaction solution temperature can be controlled independently. This allows controlling the substrate temperature and the reaction solution temperature to be the same temperature to provide a more uniform temperature of the reaction solution in the reaction vessel, or setting the substrate temperature higher than the reaction solution temperature to suppress the formation of particles (colloid) in the reaction solution to allow selective film formation on the substrate. Suppressing the formation of particles (colloid) allows repeated use of the reaction solution, thereby achieving cost reduction.

The fixing surface, on which the substrate is fixed, is made of stainless steel or titanium, and can therefore transmit the heat from the heater for heating the substrate to the substrate uniformly and at high thermal conductivity, thereby achieving highly uniform heating of the substrate. This improves the thickness uniformity of the formed layer, resulting in a buffer layer having higher quality than that of prior art buffer layers.

According to the method of forming a buffer layer of the invention, the substrate is heated to the temperature T₁ [° C.] by the heater, and then at least the surface of the photoelectric conversion semiconductor layer is brought into contact with the reaction solution, which is controlled to the temperature T₂ [° C.] lower than the temperature T₁. Therefore, the deposition starts soon after the substrate is immersed in the reaction solution, and a time taken for formation of the buffer layer is reduced compared to a case where the substrate temperature is raised after the substrate has been brought into contact with the reaction solution.

Further, setting the substrate temperature during film formation higher than the reaction solution temperature suppresses the formation of particles (colloid) in the reaction solution and allows selective film formation on the substrate. Suppressing the formation of particles (colloid) allows repeated use of the reaction solution, thereby achieving cost reduction.

### BRIEF DESCRIPTION OF THE DRAWINGS

FIG. 1 is a sectional view illustrating the schematic structure of a chemical bath deposition apparatus according to an embodiment of the present invention,

FIG. 2 is a perspective view of the chemical bath deposition apparatus shown in FIG. 1,

FIG. 3 is a cross-sectional schematic diagram illustrating a modification of a substrate holding section,

FIG. 4 is a cross-sectional schematic diagram illustrating a photoelectric conversion device of one embodiment, which is manufactured by a method of manufacturing a photoelectric conversion device of the invention,

FIG. 5 is a schematic diagram illustrating the schematic structure of a CBD apparatus used in Example 1-4 and Example 2-2,

FIG. 6 is a schematic diagram illustrating the schematic structure of a CBD apparatus used in Comparative Example 1-1 and Comparative Example 2-3, and

FIG. 7 is a schematic diagram illustrating the schematic structure of a CBD apparatus used to carry out a CBD process of Comparative Example 2-2.

### DESCRIPTION OF PREFERRED EMBODIMENTS

Hereinafter, embodiments of the present invention will be described with reference to the drawings.

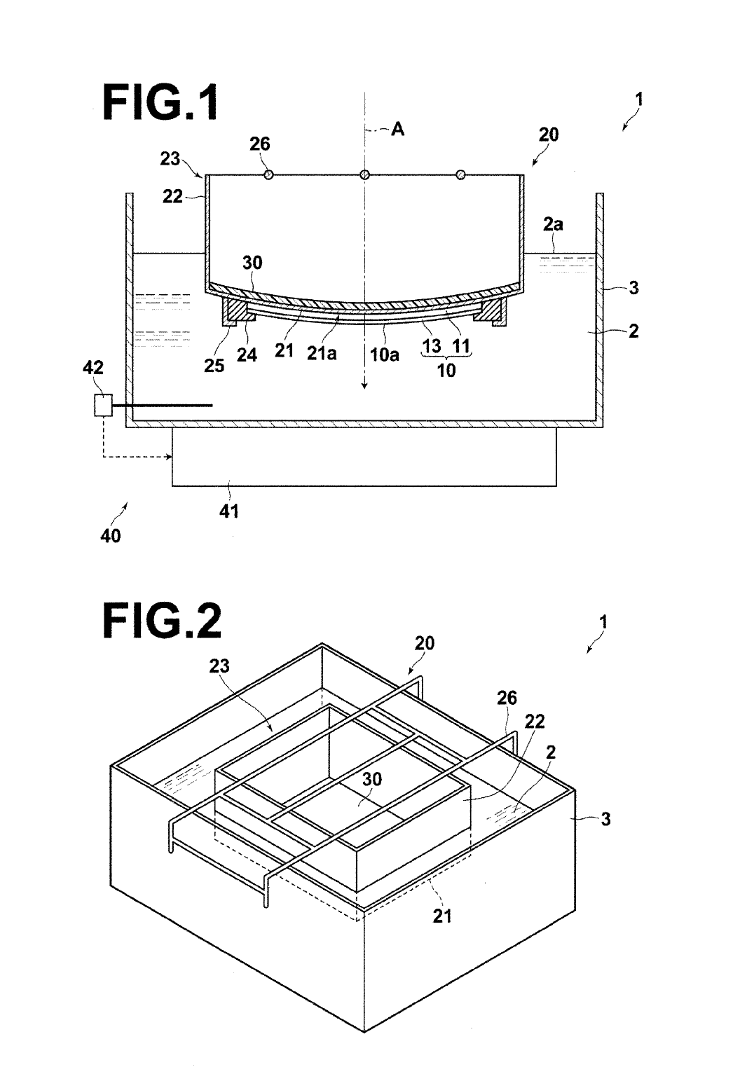

FIG. 1 is a cross-sectional schematic diagram illustrating a chemical bath deposition apparatus 1 according to an embodiment of the invention (which will hereinafter be referred to as “CBD apparatus 1”), and FIG. 2 is a perspective view illustrating the schematic structure of the CBD apparatus 1 shown in FIG. 1.

As shown in FIG. 1, the CBD apparatus 1 includes: a reaction vessel 3 containing a reaction solution 2 used to deposit a film (buffer layer) by chemical bath deposition on a surface 10a of a substrate 10; a substrate holding section (substrate holder) 20 for holding the substrate 10; a heater 30 for heating the substrate 10 from the back side thereof; and a reaction solution temperature control unit 40 for controlling the temperature of the reaction solution 2 contained in the reaction vessel 3.

The substrate holder 20 includes: a stainless steel plate member 21 forming the bottom surface of the substrate holder 20, which includes a fixing surface 21a, on which the substrate 10 is closely fixed; a holder body 23 in the form of a vessel, which includes a wall surface 22 formed continuously from the bottom surface formed by the plate member 21; and a support 26, which is connected to the holder body 23 and can be hung across a part of the reaction vessel 3.

The fixing surface 21a of the stainless steel plate member 21 has a curved (semi-cylindrical) surface which bulges outward. As shown in FIG. 1, the fixing surface 21a bulges in a semi-cylindrical shape such that the center of the fixing surface 21a in the horizontal direction in FIG. 1 is nearest to the bottom surface, and the substrate 10 is fixed along the fixing surface 21a with being bent along the curved surface thereof. The substrate 10 is held such that the surface, on which the buffer layer is formed, is oriented in the vertically downward direction (the axis A in FIG. 1) (i.e., faces the bottom surface of the reaction vessel). Fixing the substrate 10 with bending the substrate 10 in this manner minimizes adhesion of air bubbles to the surface 10a, which is now a curved surface. During film formation, air bubbles (gas) form in the reaction vessel 3. If the air bubbles adhere to the surface on which the film (buffer layer) is formed, the buffer layer is not deposited on the areas of the surface to which the air bubbles adhere, and it is difficult form a perfect film of the buffer layer. That is, in a case where the fixing surface is a flat surface and the substrate is held such that the surface on which the buffer layer is formed is horizontal relative to a reaction solution surface 2a, that is, the flat surface 10a is oriented in the vertically downward direction, the air bubbles may adhere to the surface on which the buffer layer is formed, which may result in a partially defective film of the buffer layer. In contrast, in the case where the surface 10a is bent, as in this embodiment, adhesion of the air bubbles is minimized, thereby achieving better film formation. It should be noted that, in this case, an underlying substrate 11 of the substrate 10 is flexible enough to be bent along the curvature of the fixing surface. The radius of curvature of the curved surface may preferably be in the range from 100 mm to 10000 mm, although it depends on the size of the reaction vessel, etc.

As a material forming the stainless steel plate member, SUS316 (JIS standard), which is alkali-resistant, is most preferable. The surface of stainless steel may be coated with a heat-resistant and alkali-resistant material, such as Teflon (R) or a carbon-based material (for example, a carbon material or a carbon compound, such as SiC).

In this embodiment, the substrate holder 20 is adapted to hold the substrate 10 on the fixing surface 21a with a liquid-leakage prevention jig 24, which grasps the substrate 10 against the substrate holder body 23, such that only the surface 10a (on which the buffer layer is formed) is able to contact the reaction solution 2. The substrate holder 20 is further adapted to hold the substrate 10 with a clamping frame 25, which clamps the liquid-leakage prevention jig 24 and the substrate 10 so that no reaction solution 2 penetrate through a gap between the liquid-leakage prevention jig 24 and the substrate 10. The liquid-leakage prevention jig 24 and the clamping frame 25 form an end face protective member for preventing a side end face of the substrate from contacting the reaction solution.

In the case where only the surface on which the buffer layer is formed of the substrate 10 can contact the reaction solution 2 and the substrate 10 can be held such that areas of the substrate 10 other than the outermost layer 13 do not contact the reaction solution 2 in this manner, a base material, such as an Al base material, which may possibly be eroded by the reaction solution 2, may also be used as the underlying substrate 11.

The heater 30 is a sheet heater that is uniformly disposed on the surface of the stainless steel plate member 21 of the holder body 23 opposite from the fixing surface 21a, i.e., the inner bottom surface of the holder body 23, to span over an area larger than the area of the substrate 10. In particular, in this embodiment, the heater 30 is a rubber heater. By providing the rubber heater spanning over an area larger than the area of the substrate 10, uniform heating of the substrate 10 can be achieved via the stainless steel plate member, thereby improving uniformity of the substrate temperature. The higher uniformity of the substrate temperature preferably improves the thickness uniformity of the deposited film.

The reaction solution temperature control unit 40 includes: a temperature controlling means 41 disposed on the bottom surface of the reaction vessel 3; and a temperature measuring unit 42 for measuring a reaction solution temperature around the bottom surface. The temperature controlling means 41 includes heating and/or cooling means. The heating means may be any of various heaters. The cooling means may include a water-cooling device such as one using cold water, an air-cooling device, such as a fan, a heat sink, etc.

The reaction solution temperature is defined as a reaction solution temperature in the vicinity of the temperature controlling means 41.

It may also be considered that the temperature controlling means 41 may separately include a thermostatic chamber, so that the reaction solution temperature is kept constant by circulating the reaction solution. However, it is more preferable that the reaction solution is not circulated during the film formation because circulating the reaction solution promotes formation of particles (colloid) in the reaction solution.

The CBD apparatus 1 of the invention includes the heater 30 for heating the substrate 10 and the reaction solution temperature control unit 40 for controlling the reaction solution temperature which are independent from each other, so that the temperature of the substrate 10 and the reaction solution temperature can be controlled independently. This allows controlling the substrate temperature and the reaction solution temperature to be the same temperature to provide a more uniform reaction solution temperature, or varying the substrate temperature and the reaction solution temperature (for example, raising the reaction solution temperature in the vicinity of the substrate to a reaction temperature (around 70-90° C.) and controlling the reaction solution temperature in the vicinity of the reaction solution temperature control unit to be lower than the reaction temperature) to suppress the formation of particles (colloid) in the reaction solution, thereby allowing selective film formation on the substrate.

The inner wall of the reaction vessel 3 is preferably coated with an alkali-resistant hydrophobic material. The coating of the hydrophobic material minimizes deposition of the film on the inner wall during the film deposition on the substrate, thereby saving material consumption and time and labor for maintenance.

However, even when the coating of the hydrophobic material is provided, the deposited material adheres to the inner wall after a long time of the film forming process. Such a deposited material can be dissolved and removed by washing with an aqueous hydrochloric solution, or the like. Therefore, the hydrophobic material used to coat the inner wall is preferably alkali-resistant and acid-resistant. A preferred example of the coating material is Teflon (R).

The fixing surface, on which the substrate 10 is fixed, is made of stainless steel, and can therefore transmit the heat from the substrate-heating heater 30 to the substrate uniformly and at high thermal conductivity, thereby achieving highly uniform heating of the substrate. This improves the thickness uniformity of the formed layer.

It should be noted that the same effect is provided when a titanium plate member is used in place of the stainless steel plate member including the fixing surface.

### Modification

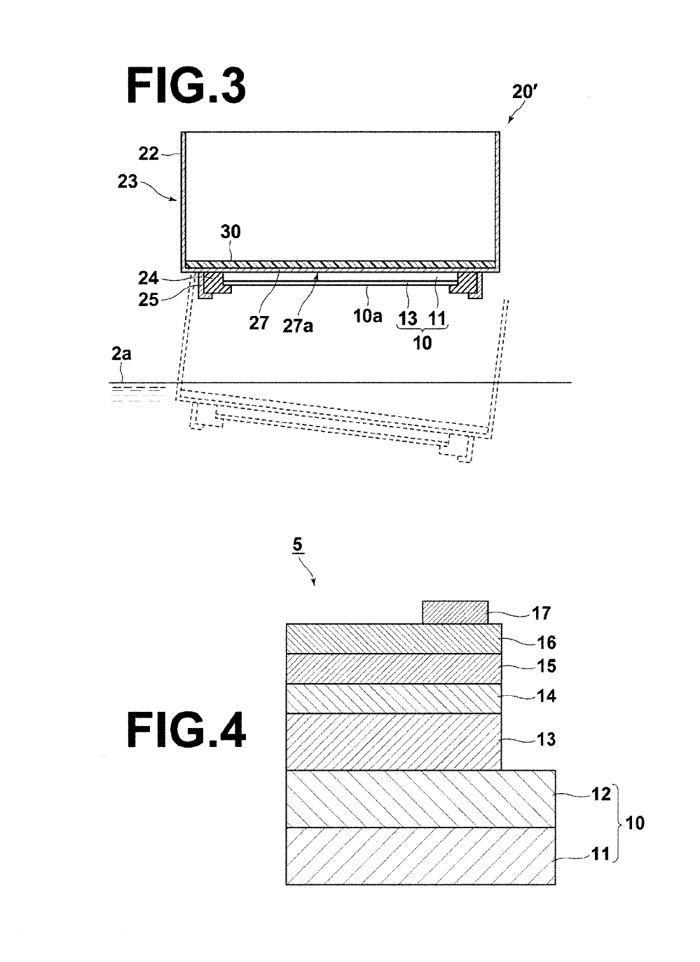

FIG. 3 is a cross-sectional schematic diagram illustrating a modification 20′ of the substrate holder. In the CBD apparatus 1 of the above-described embodiment, the substrate fixing surface 21a of the substrate holder 20 has a curved surface. In contrast, as shown in FIG. 3, a stainless steel plate member 27 may not be curved so that it has a flat fixing surface 27a. In this case, the substrate 10 may be held such that the surface 10a is inclined from the vertically downward direction (i.e., the surface 10a is inclined from the direction parallel to the surface 2a of the reaction solution) (as shown by the dashed lines in FIG. 3). The angle of inclination of the substrate is preferably in the range from 1 to 30 degrees. By inclining the surface of the substrate from the horizontal direction, the adhesion of air bubbles to a photoelectric conversion semiconductor layer 13 can be minimized, as with the case where the surface of the substrate is bent.

In the case where the substrate fixing surface 21a is a curved surface, it is necessary that the underlying substrate 11 of the substrate 10 is flexible. In contrast, in the case where the fixing surface 27a is flat, a non-flexible substrate, such as a glass substrate, may also be used.

The CBD apparatus may preferably include a plurality of material solution tanks for containing various material solutions forming the reaction solution, a tank for mixing the material solutions, and a piping line for pouring the thus prepared mixed reaction solution into the reaction vessel. Further, the CBD apparatus may preferably include a piping line for circulating and filtering the reaction solution in the reaction vessel to collect the particles (colloid), etc., formed in the reaction solution and return the solution to the reaction vessel. As descried previously, circulating the reaction solution promotes the formation of particles (colloid), and therefore it is preferable to circulate the reaction solution during interval periods between the film formation processes, not during the film formation process.

The CBD apparatus may include a transmittance measuring unit for measuring transmittance of the reaction solution. In this case, a relationship between decrease of the transmittance and the thickness of the formed film may be determined in advance, and the transmittance of the reaction solution may be measured in-situ, so that the film formation is ended based on the decrease of transmittance.

The CBD apparatus may include a pH measuring unit for measuring pH of the reaction solution. In this case, a relationship between change of the pH and the thickness of the formed film may be determined in advance, and the pH of the reaction solution may be measured in-situ, so that the film formation is ended based on the amount of change of pH.

Alternatively, the CBD apparatus may include an electric conductivity measuring unit for measuring electric conductivity of the reaction solution. In this case, a relationship between change of the electric conductivity and the thickness of the formed film may be determined in advance, and the electric conductivity of the reaction solution may be measured in-situ, so that the film formation is ended based on the amount of change of electric conductivity.

The change of transmittance, pH or electric conductivity may be used to detect the end of the useful life of the reaction solution. In addition to determining the time to replace the reaction solution, time to add a fresh reaction solution or recycled solution may be determined using the change of transmittance, pH or electric conductivity.

Metallic parts of the CBD apparatus 1 which may possibly contact the CBD solution, such as the substrate holder, may preferably be made of an alkali-resistant material, such as SUS316. The inner wall of the reaction vessel 3 may preferably be coated with Teflon (R).

In a case where the film formation is carried out in a batch process with the CBD apparatus 1 shown in FIG. 1, the substrate holder may be adapted to be rotatable so that the substrate holder is rotated during the film formation. This is believed to minimize unevenness of the deposition, thereby achieving higher uniformity of the formed film.

The CBD apparatus 1 is placed in a housing (not shown) to prevent dust, etc., from entering in the apparatus. An exhaust port for discharging the alkaline gas may preferably be provided in the housing.

The housing may preferably be provided with an antistatic function to prevent adhesion of dust. The antistatic function may be provided by applying an antistatic agent on the housing, or by forming the housing from a resin material in which an electrically conductive material is mixed.

The CBD apparatus 1 shown in FIG. 1 is configured such that a square substrate is mounted one by one on the substrate holder 20, with assuming that the film formation is carried out in a batch process. However, the invention is not limited to a batch process, and is also applicable to film formation carried out in a roll-to-roll process. In this case, the substrate holder includes a mechanism that can sequentially mount portions of a roll-shaped substrate. Specifically, in place of the stainless steel plate member including the fixing surface, the substrate holder may include a drum-shaped rotating holder body made of stainless steel, and the drum surface may be adapted such that portions of a long substrate is sequentially mounted on the fixing surface. The heater may be disposed inside the drum.

The CBD apparatus of the invention is preferably applicable to formation of a buffer layer of a photoelectric conversion device, which includes a lower electrode, a photoelectric conversion semiconductor layer, the buffer layer and a transparent electrode formed on a substrate.

Next, an embodiment of a method of forming a buffer layer of the invention is described.

In the method of this embodiment, the above-described CBD apparatus 1 is used to form a buffer layer of a photoelectric conversion device, which has a layered structure formed on a substrate, the layered structure including a lower electrode, a photoelectric conversion semiconductor layer, the buffer layer and a transparent conductive layer.

First, the substrate 10 including the lower electrode (not shown in FIGS. 1 and 2) and the photoelectric conversion semiconductor layer 13 sequentially formed on the substrate 11 is prepared (on which the buffer layer is formed), and the substrate 10 is mounted on the substrate holder 20. Then, the substrate 10 is heated by the heater to a temperature T₁ [° C.].

Then, at least the surface of the photoelectric conversion semiconductor layer 13 is brought into contact with the reaction solution, which is controlled to a temperature T₂ [° C.] lower than the temperature T₁, while the heated state of the substrate 10 is maintained (while heating the substrate 10 with the heater). As shown in FIG. 1, when the substrate 10 held by the substrate holder 20 is immersed in the reaction solution, the back side and the side end face of the substrate, which is closely fixed on the fixing surface 15 of the holding section 20 with being clamped by the liquid-leakage prevention jig 24 and the clamping frame 25, do not contact the reaction solution.

Since the substrate 10 is heated prior to immersion into the reaction solution, deposition of the buffer layer begins promptly after the substrate 10 is immersed in the reaction solution.

By immersing the substrate 10 in the reaction solution after the substrate 10 has sufficiently been heated to the reaction temperature, the deposition of the buffer layer begins earlier than a case where the substrate is heated after the substrate is immersed in the reaction solution. Therefore, time reduction of the film formation process can be achieved. In particular, use of a metallic substrate as the substrate 10 results in a higher temperature rising rate of the substrate by heating, thereby further promoting the time reduction of the film formation process.

During the film formation, the substrate temperature is maintained at T₁ by the heater 30, and the reaction solution temperature is maintained at T₂ by the reaction solution temperature control unit 40. It is believed that, after the substrate has been heated to T₁, the substrate temperature T₁ is temporarily decreased by immersing the substrate in the reaction solution with the temperature lower than T₁, and the reaction solution temperature is temporarily increased. However, the temperature setting of the heater is maintained at T₁ and the temperature setting of the temperature controlled by the reaction solution temperature control unit 40 is maintained at T₂ during the film formation.

The film formation time (reaction time) is not particularly limited. With a film formation time of, for example, 10 to 60 minutes, a layer well covering the under layer and having a sufficient thickness as the buffer layer can be formed, although it depends on the substrate temperature and the reaction solution temperature.

The heating temperature T₁ [° C.] of the substrate may be a predetermined temperature (constant temperature) in the range from 70 to 90° C., and the controlled temperature T₂ of the reaction solution [ ° C.] may be a predetermined temperature (constant temperature) of not more than 60° C., or preferably not more than 40° C.

In particular, in a case where a Zn compound layer is formed as the buffer layer, it is preferable that T₁≧70≧T₂+30. That is, T₁ is preferably 70° C. or more, and a difference between T₁ and T₂ is preferably 30° C. or more.

Since the substrate heating temperature is higher than the controlled temperature of the reaction solution, it is believed that a temperature distribution is generated in the reaction solution in the reaction vessel 3 between the vicinity of the area where the substrate is held and areas apart from the substrate. In this embodiment, the temperature of the reaction solution at an area sufficiently apart from the substrate is measured as the reaction solution temperature. Specifically, as can be seen from the CBD apparatus 1 shown in FIG. 1, the temperature controlling means 41 for the reaction solution is disposed at the bottom surface side of the reaction vessel 3 opposite from the vicinity of the liquid surface where the substrate is held, so that the temperature measuring unit 42 measures the temperature of the reaction solution in the vicinity of the bottom surface of the reaction vessel 3.

The substrate temperature of 70° C. or more raises the reaction solution temperature in the vicinity of the immersed substrate to allow sufficient deposition of the buffer layer on the substrate. On the other hand, by setting the reaction solution temperature lower than the substrate temperature, the reaction solution temperature at areas other than the area in the vicinity of the substrate is kept low, thereby suppressing the formation of particles (colloid) in the reaction solution. The reaction solution temperature of 60° C. or less can significantly suppress the deposition reaction, and the reaction solution temperature of 40° C. or less results in almost no formation of particles (colloid).

The higher the amount of particles (colloid) floating in the reaction solution, the higher the possibility of adhesion of particulate solids to the surface of the deposited film. The particulate solid refers to a solid formed by aggregated particles having a primary particle size on the order of several tens to several hundreds nanometers. If a photoelectric conversion device is produced in a state where the particulate solids (secondary aggregates) having an equivalent circle diameter of around 1 μm or more are adhering to the surface of the buffer layer, areas of the buffer layer to which the particulate solids adhere have higher resistance and hinder flow of electric current, and this may possibly result in degradation of performance of the photoelectric conversion device.

Further, during a process to form the transparent conductive layer on the buffer layer, the particulate solids (secondary aggregates) adhering to the surface of the buffer layer may be peeled off, and the buffer layer may be peeled off at the same time. This may possibly result in degradation of performance of the photoelectric conversion device.

According to the method of forming a buffer layer of the invention, the reaction solution temperature set to be lower than the substrate temperature allows reduction of the formation of particles (colloid) compared to a case where the entire reaction solution is heated to a deposition temperature, thereby minimizing adhesion of the particulate solids to the surface of the deposited film. Further, the relatively high substrate temperature allows selective film deposition on the substrate. Still further, coating the inner wall of the reaction vessel with Teflon (R) can enhance the effect of reducing the deposition on the inner wall of the reaction vessel. Yet further, the low reaction solution temperature of 60° C. or less, or 40° C. or less, allows more active reduction of the formation of particles (colloid).

The formation of particles (colloid) promotes decrease of transmittance (decrease of transparency) of the reaction solution. Minimizing the formation of particles (colloid), therefore, minimizes the decrease of transmittance (decrease of transparency) of the reaction solution. While the transparency of the reaction solution is high enough, the reaction solution can be repeatedly used, and this allows reducing the cost of forming the buffer layer.

It is preferable that, during the film formation, the reaction solution is not stirred vigorously or not stirred at all. The stirring may be achieved using a stirrer, or may be achieved by circulating the reaction solution or applying an ultrasonic wave to the reaction solution. Stirring the reaction solution promotes the formation of particles (colloid) in the reaction solution and increases the amount of particles (colloid) in the reaction solution. This increases the possibility of adhesion of the particulate solids to the surface of the deposited film.

Patent Document 1 mentioned above in the BACKGROUND ART section teaches, in the embodiment thereof, that the solution concentration is controlled to be constant by circulating the reaction solution. However, in a case where the reaction solution is circulated at a rate higher than a certain rate, the difference between the substrate temperature and the reaction solution temperature is reduced. In contrast, in the case where the reaction solution is not circulated, the difference between the substrate temperature and the reaction solution temperature can be maintained better, and this is more advantageous to achieve the selective deposition on the substrate.

By forming the buffer layer without stirring the reaction solution, the formation of the particulate solids is reduced compared to the case where the reaction solution is stirred.

After the buffer layer has been formed, the substrate holder holding the substrate is lifted out of the reaction solution, and the substrate having the buffer layer formed on the photoelectric conversion semiconductor layer is removed from the substrate holder. Before the substrate is removed from the holder, the substrate held on the holder may be washed in this state with water to a certain extent. Eventually, the substrate having the buffer layer formed thereon and removed from the holder is sufficiently washed with water, and thereafter, the water is removed by a water removal mechanism, such as air knife. In the case where the buffer layer is a Zn compound layer, i.e., a ZnS, Zn(S,O) or Zn(S,O,OH) layer, the buffer layer may be annealed at a temperature in the range from 150° C. to 230° C., or preferably in the range from 170° C. to 210° C., for 5 minutes to 60 minutes (some Zn compound layers require annealing to exhibit good performance, while some Zn compound layers do not). The annealing method is not particularly limited; however, heating with hot air using a commercially-available oven, electric furnace, vacuum oven, or the like, is preferred. By conducting the heat treatment in this manner, properties of the photoelectric conversion device, such as conversion efficiency, can be improved.

A relationship between the film formation time and the thickness of a formed film under predetermined conditions may be examined in advance, and the formation of the buffer layer may be ended when a certain film formation time to achieve a desired film thickness has been elapsed.

Alternatively, a relationship between the change of transmittance of the reaction solution and the thickness of a formed film may be examined in advance, and the transmittance of the reaction solution may be measured in-situ to end the film formation based on decrease of the transmittance.

Further alternatively, a relationship between the change of pH of the reaction solution and the thickness of a formed film may be examined in advance, and the pH of the reaction solution may be measured in-situ to end the film formation based on the amount of change of pH. Still alternatively, a relationship between the change of electric conductivity of the reaction solution and the thickness of a formed film may be examined in advance, and the electric conductivity of the reaction solution may be measured in-situ to end the film formation based on the amount of change of the electric conductivity.

According to the invention, the buffer layer is formed by a chemical bath deposition (CBD) process.

The “CBD process” is a process to deposit a thin metallic compound film on a substrate at an appropriate rate in a stable environment by forming a complex of a metal ion M using, as the reaction solution (chemical bath deposition solution), a metal ion solution having a concentration and a pH that achieve a supersaturated condition by an equilibrium represented by the general formula below:

[M(L)₁]^{m+}≈Mⁿ⁺+iL

(wherein, M represents a metallic element, L represents a ligand, and m, n and i independently represent a positive number.)

The buffer layer is not particularly limited; however, the buffer layer preferably contains a metal sulfide that contains Cd, Zn or In, such as CdS, ZnS, Zn(S,O) and/or Zn(S,O,OH), InS, In(S,O) and/or In(S,O,OH). The thickness of the buffer layer is preferably in the range from 5 nm to 2 μm, more preferably in the range from 10 to 200 nm or even more preferably in the range from 10 to 100 nm.

The chemical bath deposition solution (reaction solution) for depositing the buffer layer contains at least a metal (M), such as Cd, Zn or In, and a sulfur source. Using this solution, the above-described buffer layer can be formed. The sulfur source may be a compound containing sulfur, such as thiourea (CS(NH₂)₂) or thioacetamide (C₂H₅NS), or thiosemicarbazide, thiourethane, diethylamine, triethanolamine, or the like.

The concentration of each component of the reaction solution is not particularly limited as long as a desired buffer layer can be deposited.

In a case where a CdS buffer layer is formed, a mixed solution containing the sulfur source, a Cd compound (such as cadmium sulfate, cadmium acetate, cadmium nitrate, cadmium chloride, or a hydrate thereof), and an aqueous ammonia or ammonium salt (such as CH₃COONH₄, NH₄Cl, NH₄I, (NH₄)₂SO₄, or the like) can be used as the reaction solution.

In a case where a buffer layer formed by a Zn compound layer free of Cd, such as ZnS, Zn(S,O), Zn(S,O,OH), or the like, is formed, a mixed solution free of Cd, such as a mixed solution containing the sulfur source, a Zn compound (such as zinc sulfate, zinc acetate, zinc nitrate, zinc chloride, zinc carbonate, or a hydrate thereof), and an aqueous ammonia or ammonium salt (examples thereof are the same as those listed above) can be used as the reaction solution.

It should be noted that, in the case where the buffer layer formed by a Zn compound layer is formed, the reaction solution preferably contains a citrate compound (trisodium citrate and/or a hydrate thereof). When the reaction solution containing the citrate compound is used, formation of the complex is facilitated and crystal growth by the CBD reaction is well controlled, thereby allowing stable film formation.

As shown as the CBD apparatus 1 of this embodiment, in the case where the substrate fixing surface 21a of the substrate holder 20 is a curved surface, it is suitable for formation of the buffer layer on a flexible substrate. On the other hand, in the case where the fixing surface 27a of the substrate holder 20′ is a flat surface, as in the modification shown in FIG. 3, it is applicable to either of flexible and non-flexible substrates.

The CBD apparatus 1 shown in FIG. 1 is configured such that a square substrate is mounted one by one on the substrate holder 20, with assuming that the film formation is carried out in a batch process. However, the method of forming a buffer layer of the invention is not limited to one that uses the apparatus shown in FIG. 1, and is applicable to any CBD apparatus that can independently control the substrate temperature and the reaction solution temperature.

Further, the method of forming a buffer layer of the invention is not limited to a batch process, and is also applicable to film formation carried out in a roll-to-roll process.

The substrate 10 used in the above-described embodiment includes at least the underlying substrate 11, the lower electrode (not shown) formed thereon, and the photoelectric conversion semiconductor layer 13, which forms the outermost surface.

Specific examples of the underlying substrate 11 may include a glass substrate, a metallic substrate, such as stainless steel, with an insulating film formed on the surface thereof, a resin substrate, such as polyimide, etc. When the apparatus as shown in FIG. 1 is used, the substrate needs to be a flexible substrate, specifically, a flexible glass substrate, a flexible metallic substrate or a flexible polyimide substrate. When the other apparatus having the flat substrate fixing surface is used, a non-flexible substrate (such as a glass substrate having a thickness around 0.5 mm to 2 mm) may also be used.

In the case where the substrate holder 20 includes the end face protective member, as in the CBD apparatus 1 of this embodiment, even if the underlying substrate 11 contains a component that dissolves in the CBD reaction solution, elution of such a component from the substrate does not occur. This is particularly advantageous when the substrate contains a metal that may forma complex ion with a hydroxide ion, more particularly, when the substrate contains Al.

Next, the method of manufacturing a photoelectric conversion device of the invention is described.

FIG. 4 shows a schematic sectional view of one embodiment of the photoelectric conversion device manufactured by the method of manufacturing a photoelectric conversion device of the invention. For ease of visual recognition, elements shown in the drawing are not to scale.

The photoelectric conversion device shown in FIG. 4 includes a lower electrode (back side electrode) 12, a photoelectric conversion semiconductor layer 13, a buffer layer 14, a window layer 15, a transparent conductive layer (transparent electrode) 16 and an upper electrode (grid electrode) 17, which are sequentially formed on the substrate 11.

The method of manufacturing a photoelectric conversion device of the invention is characterized by that, in the method of manufacturing a photoelectric conversion device having a layered structure including at least the lower electrode 12, the photoelectric conversion semiconductor layer 13, the buffer layer 14 and the transparent conductive layer 16 formed on the substrate 11, the buffer layer is formed by the method of forming a buffer layer of the invention.

Methods for forming the layers other than the buffer layer are not particularly limited. Now, examples of the methods for forming the substrate and the individual layers are briefly described.

### Substrate

Specific examples of the substrate 11 may include:

a glass substrate;

a metallic substrate, such as stainless steel, having an insulating film formed on the surface thereof;

an anodized substrate having an anodized film mainly composed of Al₂O₃ formed on at least one side of an Al base material mainly composed of Al;

an anodized substrate having an anodized film mainly composed of Al₂O₃ formed on at least one side of a composite base material, which is formed by combining an Al material mainly composed of Al on at least one side of a Fe material mainly composed of Fe;

an anodized substrate having an anodized film mainly composed of Al₂O₃ formed on at least one side of a base material, which has an Al film mainly composed of Al formed on at least one side of a Fe material mainly composed of Fe; and

a resin substrate, such as polyimide.

Further, the substrate may include a soda-lime glass (SLG) layer. The soda-lime glass layer serves to diffuse Na into the photoelectric conversion layer. When the photoelectric conversion layer contains Na, the photoelectric conversion efficiency is further improved.

As described previously, the method of forming a buffer layer of the invention is applicable to either of flexible and non-flexible substrates.

However, in the case where the substrate fixing surface 21a of the substrate holder 20 is a curved surface, as shown as the CBD apparatus 1 of this embodiment, it is necessary to use a flexible substrate.

Further, in the case where an apparatus, such as the CBD apparatus 1 shown in FIG. 1, which is able to protect the back side and the end face of the substrate with the liquid-leakage prevention jig and the clamping frame is used, a substrate that contains a component that dissolves in the CBD reaction solution can be used. Specifically, the above-listed anodized substrates containing Al, which may form a complex ion with a hydroxide ion, can be used.

### Lower Electrode

The main component of the lower electrode 12 is not particularly limited; however, it may preferably be Mo, Cr, W or a combination thereof, in particular, Mo, etc. The thickness of the lower electrode 12 is not particularly limited; however, it may preferably be in the range from about 200 to 1000 nm. The lower electrode 12 may, for example, be formed on the substrate using a sputtering process.

### Photoelectric Conversion Semiconductor Layer

The main component of the photoelectric conversion semiconductor layer 13 is not particularly limited; however, in view of providing high photoelectric conversion efficiency, it may preferably be at least one compound semiconductor having a chalcopyrite structure, more preferably, at least one compound semiconductor containing a group Ib element, a group IIIb element and a group VIb element.

The main component of the photoelectric conversion semiconductor layer 13 may preferably be at least one compound semiconductor containing:

at least one group Ib element selected from the group consisting of Cu and Ag,

at least one group IIIb element selected from the group consisting of Al, Ga and In, and

at least one group VIb element selected from the group consisting of S, Se, and Te.

Examples of the compound semiconductor include:

CuAlS₂, CuGaS₂, CuInS₂,

CuAlSe₂, CuGaSe₂,

AgAlS₂, AgGaS₂, AgInS₂,

AgAlSe₂, AgGaSe₂, AgInSe₂,

AgAlTe₂, AgGaTe₂, AgInTe₂,

Cu(In,Al)Se₂, Cu(In,Ga) (S,Se)₂,

Cu_{1-z}In₁₋ₓGaₓSe_{2-y}S_{y} (wherein 0≦x≦1,0≦y≦2,0≦z≦1) (CI(G)S)

Ag(In,Ga)Se₂, and Ag(In,Ga) (S,Se)₂.

Examples of the compound semiconductor may further include Cu₂ZnSnS₄, Cu₂ZnSnSe₄, Cu₂ZnSn(S,Se)₄, CdTe, (Cd,Zn)Te, etc.

The thickness of the photoelectric conversion semiconductor layer 13 is not particularly limited; however, it may preferably be in the range from 1.0 to 4.0 μm, or particularly preferably be in the range from 1.5 to 3.5 μm.

The method for forming the photoelectric conversion semiconductor layer 13 is not particularly limited, and the photoelectric conversion semiconductor layer 13 may be formed by a vacuum deposition process, a sputtering process, a MOCVD process, or the like.

### Buffer Layer

The buffer layer 14 is formed by the method of forming a buffer layer of the invention as described above. The conductivity type of the buffer layer 14 is not particularly limited; however, n-type is preferable. The thickness of the buffer layer 14 is not particularly limited; however, it may preferably be in the range from 5 nm to 2 μm, more preferably be in the range from 10 to 200 nm, or even more preferably be in the range from 10 to 100 nm. The details of the buffer layer are as described above.

### Window Layer

The window layer 15 is an intermediate layer serves to take in light. The composition of the window layer 15 is not particularly limited; however, it may preferably be i-ZnO, etc. The thickness of the window layer 15 is not particularly limited; however, it may preferably be in the range from 10 nm to 2 μm, or more preferably be in the range from 15 to 200 nm. The method for forming the window layer 15 is not particularly limited; however, a sputtering process or a MOCVD process is suitable. Since the buffer layer 14 is formed by the liquid phase process, it may be preferable to use a liquid phase process in view of simplifying the manufacturing process. The window layer is optional, i.e., the photoelectric conversion device may not include the window layer 15.

### Transparent Conductive Layer

The transparent conductive layer 16 serves to take in light and also serves as an electrode, which forms a pair with the lower electrode 12 and an electric current generated at the photoelectric conversion semiconductor layer 13 flows therethrough. The composition of the transparent conductive layer 16 is not particularly limited; however, it may preferably be n-ZnO, such as ZnO:Al, ZnO:Ga, ZnO:B, etc. The thickness of the transparent conductive layer 16 is not particularly limited; however, it may preferably be in the range from 50 nm to 2 μm. The method for forming the transparent conductive layer 16 is not particularly limited; however, a sputtering process or a MOCVD process is suitable, as with the window layer. In view of simplifying the manufacturing process, use of a liquid phase process may also be preferable.

### Upper Electrode

The main component of the upper electrode 17 is not particularly limited; however, it may be Al, etc. The thickness of the upper electrode 17 is not particularly limited; however, it may preferably be in the range from 0.1 to 3 μm.

It should be noted that, in a case of an integrated solar battery formed by integrating a number of photoelectric conversion devices (cells), the upper electrode is provided at a cell that serves as a power output end among the cells connected in series.

The photoelectric conversion device 5 manufactured by the manufacturing method of this embodiment has the above-described configuration.

The photoelectric conversion device 5 is preferably applicable to applications, such as solar batteries. A solar battery can be formed by attaching a cover glass, a protective film, etc., to the photoelectric conversion device 5, as necessary.

The photoelectric conversion device manufactured according to the manufacturing method of the invention is applicable not only to solar batteries but also to other applications, such as CCDs.

### EXAMPLES

Now, examples where the CBD apparatus of the invention was used and comparative examples are described.

### Substrate

The substrate includes the lower electrode and the photoelectric conversion semiconductor layer 13, which are formed on the underlying substrate 11.

The substrate used was an anodized substrate including an aluminum anodized film (AAO) formed on an Al surface of a composite base material formed by 100 μm-thick stainless steel (SUS) and 30 μm-thick Al, with a soda lime glass (SLG) layer, a Mo electrode layer, and the photoelectric conversion semiconductor layer sequentially formed on the AAO surface. Specifically, the SLG layer and the Mo electrode layer were formed by sputtering, and a Cu(In_{0.7}Ga_{0.3})Se₂ layer was formed as the photoelectric conversion semiconductor layer by a three stage process. The thicknesses of these layers were as follows: SUS (100 μm), Al (30 μm), AAO (20 μm), SLG (0.2 μm), Mo (0.8 μm) and CIGS (1.8 μm). The size of the substrate was 10 cm×10 cm.

### Surface Treatment

A reaction vessel containing a 10% aqueous KCN solution was prepared, and the surface of the CIGS layer, which is the substrate surface on which the buffer layer is formed, was immersed in the solution for 3 minutes at room temperature to remove impurities from the surface of the CIGS layer. After the substrate was removed from the solution, the substrate was sufficiently washed with water.

### Preparation of Reaction Solution I

An aqueous zinc sulfate solution (0.18 [M]) was prepared as an aqueous solution (I) of a component (Z), an aqueous thiourea solution (0.30 [M] thiourea) was prepared as an aqueous solution (II) of a component (S), an aqueous trisodium citrate solution (0.18 [M]) was prepared as an aqueous solution (III) of a component (C), and an aqueous ammonia (0.30 [M]) was prepared as an aqueous solution (IV) of a component (N). Then, the same volume of the aqueous solutions I, II and III were mixed to form a mixed solution containing 0.06 [M] zinc sulfate, 0.10 [M] thiourea and 0.06 [M] trisodium citrate, and the same volume of the mixed solution and the 0.30 [M] aqueous ammonia were mixed to provide the CBD solution (reaction solution) When the aqueous solutions (I) to (IV) were mixed, the aqueous solution (IV) was added lastly. In order to provide a transparent reaction solution, it is important to add the aqueous solution (IV) lastly. The thus obtained reaction solution was filtered using a filter having a mesh size of 0.22 μm. The pH of the finally obtained reaction solution was 10.3. When this reaction solution I is used, a buffer layer formed by a Zn(S,O) film is obtained.

### Preparation of Reaction Solution IT

Predetermined amounts of an aqueous CdSO₄ solution, an aqueous thiourea solution and an aqueous ammonia solution were mixed to prepare a CBD solution (reaction solution II) containing 0.0015M CdSO₄, 0.05M thiourea and 1.5M ammonia. The pH of the finally obtained reaction solution II was 12.0. When this reaction solution II is used, a buffer layer formed by a CdS film is obtained.

### Example 1-1

The prepared substrate was set on the substrate holding section of the CBD apparatus shown in FIG. 1.

Before the surface of the substrate was brought into contact with the reaction solution, the heater was turned on to heat the substrate to 90° C.

Thereafter, as shown in FIG. 1, the substrate holding section was brought down to immerse the substrate in the reaction solution I with the reaction solution temperature controlled to 40° C., and the buffer layer was deposited on the surface of the photoelectric conversion semiconductor layer. The deposition time was 30 minutes. During the deposition period, the heating of the substrate with the heater (the set temperature was 90° C.) and the control of the reaction solution temperature (the set temperature was 40° C.) were continued.

### Example 1-2

In Example 1-2, the CBD apparatus shown in FIG. 1 including the substrate holding section 20′ shown in FIG. 3, which has the flat substrate fixing surface, was used. In Example 1-2, the substrate was immersed in the reaction solution with the fixing surface inclined from the horizontal plane 2a, as shown by the dashed lines in FIG. 3. Except these points, deposition of the buffer layer was conducted in the same manner as in Example 1-1.

### Example 1-3

In Example 1-3, the same apparatus as in Example 1-2 was used. However, the substrate was immersed in the reaction solution with the fixing surface kept in parallel with the horizontal plane 2a. Except these points, deposition of the buffer layer was conducted in the same manner as in Examples 1-1 and 1-2.

### Example 1-4

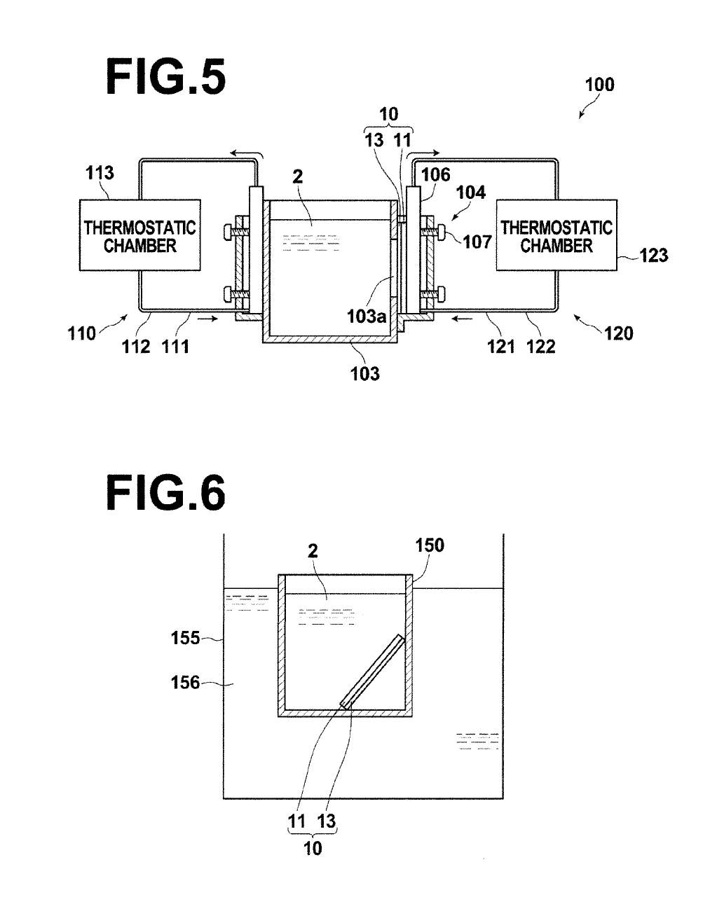

In Example 1-4, a CBD apparatus 100 schematically shown in FIG. 5 was used. The CBD apparatus 100 includes: a reaction vessel 103, which can contain the reaction solution 2 (the reaction solution I in this example); an opening 103a, which is smaller than the size of the substrate 10, formed in the wall surface of the reaction vessel 103; a substrate holding section (substrate holder) 104 for holding the substrate 10 on the outer side wall surface of the reaction vessel 103 at a position corresponding to the opening 103a, such that the entire opening 103a is covered with the substrate 10; a reaction solution temperature control unit 110; and a substrate heating control unit 120.

The substrate holder 104 includes a back plate 106 (which also serves as a part of a constant-temperature water circulation path, which will be described later) that can uniformly press the entire back side of the substrate 10, and screw members 107 that can press the back plate 106 toward the opening 103a. This substrate holder 104 holds the substrate parallel to the side wall surface of the reaction vessel.

The reaction solution temperature control unit 110 includes a constant-temperature water circulation path 112 for controlling the reaction solution temperature, which is disposed externally to the reaction vessel 103 and circulates constant-temperature water 111 to heat or cool the reaction solution 2 from outside the reaction vessel 103, and a thermostatic chamber 113 for maintaining the constant temperature of the water.

The substrate heating control unit 120 includes a constant-temperature water circulation path 122 for heating the substrate, which is disposed at the back side of the substrate and circulates constant-temperature water 121 to heat the substrate 10 from the back side of the substrate, and a thermostatic chamber 123 for maintaining the constant temperature of the water. That is, the CBD apparatus 100 includes a mechanism (the reaction solution temperature control unit 110) for controlling the reaction solution temperature introduced into the CBD apparatus at a predetermined temperature separately (independently) from a mechanism (the substrate heating control unit 120) for heating the back side of the substrate, so that the reaction solution temperature and the substrate temperature can be controlled independently from each other.

In Example 1-4, the substrate was set on the substrate holder and heated to 90° C. Then, 15 minutes after the start of heating of the substrate, the reaction solution I with the temperature thereof controlled to 40° C. was poured into the reaction vessel, and deposition of the buffer layer was conducted for 30 minutes. During the buffer layer deposition period, a state where the constant-temperature water 121 at 90° C. and the constant-temperature water 122 at 40° C. were circulated was maintained by the substrate heating control unit 120 and the reaction solution temperature control unit 110, respectively.

### Example 1-5

In Example 1-5, the same CBD apparatus as in Example 1-1 was used. Deposition of the buffer layer was conducted in the same manner as in Examples 1-1 except that the reaction solution II was used, the substrate heating temperature was 80° C., and the film formation time was 4 minutes.

### Comparative Example 1-1

In Comparative Example 1-1, the prepared reaction solution 2 (the reaction solution I in this example) was poured into a reaction vessel 150 formed by a glass beaker, as schematically shown in FIG. 6. Then, in a state where the substrate (substrate 10) was leaned against the inner wall of the reaction vessel with the surface on which the film was to be deposited facing down, the reaction vessel 150 was immersed in constant-temperature water 156 in a thermostatic chamber 155 to heat the reaction solution to 90° C., and deposition of the buffer layer was conducted for 60 minutes after the reaction solution was heated to 90° C. In Comparative Example 1-1, the substrate was heated via the reaction solution.

### Evaluation of Film Thickness

In order to evaluate the film thickness of each buffer layer covering the CIGS layer, cross sections of the buffer layer were exposed by focused ion beam (FIB) machining after a protective film was formed on the surface of the buffer layer, and SEM observation of the cross section was conducted. From these cross sectional SEM images, the film thickness was measured at total of 35 points and an average of the measurements was calculated, as shown in Table 2.

Specifically, for each of five points including the center point in the substrate plane of a 10 cm×10 cm substrate and points 3 cm apart from the center point in four directions (upward, downward, rightward, and leftward directions) in the substrate plane, the thickness was measured at seven points from each SEM image to measure the thickness at the total of 35 points, and an average film thickness and a standard deviation of the film thicknesses were calculated.

### Evaluation of Number of Particles Adhering to Film Surface

Presence of aggregations of particles having a primary particle size on the order of several tens to several hundreds nanometers adhering to the film surface (aggregations found when the film surface was observed from right above) in a field of view of 100 μm×100 pin was evaluated according to the following criteria. Good (A): The number of aggregations having an equivalent circle diameter of 3 μm or more was at most three.

Acceptable (B): The number of aggregations having an equivalent circle diameter of 3 μm or more was in the range from 4 to 10.
Bad (C): The number of aggregations having an equivalent circle diameter of 3 μm or more was 11 or more.

### Evaluation of Pin Holes in Film Due to Adhesion of Air Bubbles

In the case where the film is formed on the CIGS layer using the CBD process, the presence of the film can be visually checked based on interference thereof even when the film is a very thin film having a thickness of less than 100 nm. Therefore, first, areas without the film were checked by visual evaluation. The result of the visual evaluation was evaluated according to the following criteria.

Bad (C): Areas without the film occupied 5% or more of the area of the substrate.
Acceptable (B): Areas without the film occupied less than 5% of the area of the substrate; however, not 0.
Good (A): There was no area without the film.
Further, for each of the thus evaluated samples, the areas without the film determined by the visual evaluation were subjected to SEM observation to confirm that no film was present on the areas.

It should be noted that, if air bubbles are present on the surface of the CIGS layer, the reaction solution does not contact the areas with the air bubbles of the surface, on which the film is intended to be deposited, and no deposition proceeds at such areas.

### Evaluation of Elution of Substrate

The amount of Al [ppm] eluted in the reaction solution was measured after the film formation.

After each of the buffer layers of the above-described examples and comparative example was deposited, 2.5 mL of the CBD reaction solution was diluted ten times using a 25 ml, measuring flask, and Al concentration was measured using a SPS3000 ICP emission spectrophotometer (minimum determination limit: Al (<1 ppm)). Each sample was measured twice, and an average of the measurements was calculated.

The samples of Examples 1-1 to 1-5 were immersed in the reaction solution with the end face of the substrate protected, and therefore no elution of Al was observed. The sample of Comparative Example 1-1 did not have the end face protected, and the amount of elution of Al in the reaction solution after the film formation was 31 ppm.

TABLE 1

| | | | | | | Comparative |
|---|---|---|---|---|---|---|
| | Example 1-1 | Example 1-2 | Example 1-3 | Example 1-4 | Example 1-5 | Example 1-1 |
| Shape of substrate fixing | Semi-cylindrical | Flat surface/ | Flat surface/ | Flat surface/ | Semi-cylindrical | No substrate |
| surface/ | surface/ | Inclined from | Vertically | Positioned along | surface/ | holding section/ |
| Position during film formation | vertically | vertically | downward | vertical direction | vertically | leaned |
| | downward | downward | | | downward | |
| | | direction | | | | |
| Heating mechanism of | Provided | Provided | Provided | Provided | Provided | None |
| substrate holding section | | | | | | |
| Substrate back side heating | 90 | 90 | 90 | 90 | 80 | Heated via |
| temperature [° C.] | | | | | | reaction solution |
| Start of heating of substrate | 15 minutes | 15 minutes | 15 minutes | 15 minutes | 15 minutes | — |
| holding section | before | before | before | before | before | |
| | immersion in | immersion in | immersion in | immersion in | immersion in | |
| | reaction | reaction | reaction | reaction | reaction | |
| | solution | solution | solution | solution | solution | |
| Reaction solution | I | I | 1 | I | II | I |
| Controlled temperature of | 40 | 40 | 40 | 40 | 40 | 90 |
| reaction solution [° C.] | | | | | | |
| Film formation time | 30 min | 30 min | 30 min | 30 min | 4 min | 60 min |
| Film thickness [nm] | 24 | 22 | 20 | 27 | 44 | 51 |
| Standard deviation of film | 3 | 4 | 4 | 5 | 4 | 10 |
| thickness [nm] | | | | | | |
| Deposition rate [nm/min] | 0.8 | 0.7 | 0.7 | 0.9 | 11 | 0.9 |
| Evaluation of number of | A | A | A | A | A | C |
| adhering particles | | | | | | |
| Pin holes due to adhesion | A | A | B | A | A | A |
| of air bubbles | | | | | | |
| Transmittance of reaction | 86.4 | 85.6 | 84.9 | 82.5 | 76.1 | 4.8 |
| solution after film formation | | | | | | |
| [%] | | | | | | |

As can be seen from Table 1, in the examples using the CBD apparatus of the invention, the adhesion of particles to the surface on which the buffer layer was formed was successfully minimized.

In Examples 1-1 to 1-4, where the reaction solution temperature was set lower than the substrate temperature, good films with a very small number of adhering particles (colloid) were obtained. Further, the transmittance of the reaction solution was 80% or more in all the Examples 1-1 to 1-4, and this clearly means that the formation of particles (colloid) was suppressed.

In the case where the shape of the substrate holding section was a semi-cylindrical surface, the formation of pin holes in the buffer layer was also minimized. The reason of this is believed that air bubbles ascended along the curve, thereby minimizing the adhesion of air bubbles to the surface on which the buffer layer was formed. It should be noted that, even when the flat substrate holding section was used, the formation of pin holes due to the adhesion of air bubbles was reduced in the case where the substrate was held with being inclined (Example 1-2) compared to the case where the substrate was not inclined (Example 1-3).

The standard deviation of the film thickness in the examples of the invention tended to be somewhat smaller. It is expected that the effect of uniformizing the film thickness of the invention will be more apparent when a thicker buffer layer is formed.

The inner wall of the reaction vessel used in Examples 1-1 to 1-5 was coated with Teflon (R), resulting in very small adhesion of the deposited film on the inner wall. In contrast, in Comparative Example 1-1, the reaction vessel used was a glass beaker, which was not coated with Teflon (R), resulting in heavy adhesion of the deposited film on the inner wall.

Next, examples according to the method of manufacturing a photoelectric conversion device of the invention and comparative examples are described.

### Substrate

The substrate includes the lower electrode and the photoelectric conversion semiconductor layer 13, which are formed on the underlying substrate 11. The following two types of substrates were prepared.

### Substrate I

A substrate I used was an anodized substrate including an aluminum anodized film (AAO) formed on an Al surface of a composite base material formed by 100 μm-thick stainless steel (SUS) and 30 μm-thick Al, with a soda lime glass (SLG) layer, a Mo electrode layer, and the photoelectric conversion semiconductor layer sequentially formed on the AAO surface. Specifically, the SLG layer and the Mo electrode layer were formed by sputtering, and a Cu (In_{0.7}Ga_{0.3}) Se₂ layer was formed as the photoelectric conversion semiconductor layer by a three stage process. The thicknesses of these layers were as follows: SUS (100 μm), Al (30 μm), AAO (20 μm), SLG (0.2 μm), Mo (0.8 μm) and CIGS (1.8 μm). The size of the substrate was 10 cm×10 cm.

### Substrate II

A substrate II used was a soda lime glass (SLG) substrate with a Mo electrode layer, on which a GIGS layer was formed. Specifically, the Mo lower electrode having a thickness of 0.8 μm was formed on the soda lime glass (SLG) substrate by sputtering, and the Cu (In_{0.7}Ga_{0.3}) See layer having a thickness of 1.8 μm was formed on the Mo lower electrode using a three stage process. The size of the substrate II was 3 cm×3 cm.

### Surface Treatment

A reaction vessel containing a 10% aqueous KCN solution was prepared, and the surface of the GIGS layer, which is the substrate surface on which the buffer layer is formed, was immersed in the solution for 3 minutes at room temperature to remove impurities from the surface of the GIGS layer. After the substrate was removed from the solution, the substrate was sufficiently washed with water.

### Preparation of Reaction Solution

An aqueous zinc sulfate solution (0.18 [M]) was prepared as an aqueous solution (I) of a component (Z), an aqueous thiourea solution (0.30 [M] thiourea) was prepared as an aqueous solution (II) of a component (S), an aqueous trisodium citrate solution (0.18 [M]) was prepared as an aqueous solution (III) of a component (C), and an aqueous ammonia (0.30 [M]) was prepared as an aqueous solution (IV) of a component (N). Then, the same volume of the aqueous solutions I, II and III were mixed to form a mixed solution containing 0.06 [M] zinc sulfate, 0.10 [M] thiourea and 0.06 [M] trisodium citrate, and the same volume of the mixed solution and the 0.30 [M] aqueous ammonia were mixed to provide the CBD solution (reaction solution). When the aqueous solutions (I) to (IV) were mixed, the aqueous solution (IV) was added lastly. In order to provide a transparent reaction solution, it is important to add the aqueous solution (IV) lastly. The thus obtained reaction solution was filtered using a filter having a mesh size of 0.22 μm. The pH of the finally obtained reaction solution was 10.3.

### CBD Process

Using the reaction solution prepared as described above, a Zn(S,O) film was formed as the buffer layer under conditions of examples and comparative examples.

With respect to Examples 2-1 to 2-3, the substrate was heated in advance to the temperature T₁, and the substrate was immersed in the reaction solution at the temperature T₂, where the condition: the substrate heating temperature T₁> the controlled temperature of the reaction solution T₂ was satisfied, to form the buffer layer.

Now, the examples and comparative examples are described. Major conditions are also shown in Table 2.

### Example 2-1

In Example 2-1, the CBD apparatus 1 shown in FIG. 1 was used.

The substrate I was set on the substrate holder and heated to 90° C. 15 minutes after the start of heating, the substrate was immersed in the reaction solution with the temperature controlled to 40° C., and deposition of the buffer layer was conducted for 30 minutes.

### Example 2-2

In Example 2-2, the CBD apparatus 100 schematically shown in FIG. 5 was used. The CBD apparatus 100 includes: a reaction vessel 103, which can contain the reaction solution 2; an opening 103a, which is smaller than the size of the substrate 10, formed in the wall surface of the reaction vessel 103; a substrate holding section (substrate holder) 104 for holding the substrate 10 on the outer side wall surface of the reaction vessel 103 at a position corresponding to the opening 103a, such that the entire opening 103a is covered with the substrate 10; a reaction solution temperature control unit 110; and a substrate heating control unit 120.

The substrate holder 104 includes a back plate 106 (which also serves as a part of a constant-temperature water circulation path, which will be described later) that can uniformly press the entire back side of the substrate 10, and screw members 107 that can press the back plate 106 toward the opening 103a.

The reaction solution temperature control unit 110 includes a constant-temperature water circulation path 112 for controlling the reaction solution temperature, which is disposed externally to the reaction vessel 103 and circulates constant-temperature water 111 to heat or cool the reaction solution 2 from outside the reaction vessel 103, and a thermostatic chamber 113 for maintaining the constant temperature of the water.

The substrate heating control unit 120 includes a constant-temperature water circulation path 122 for heating the substrate, which is disposed at the back side of the substrate and circulates constant-temperature water 121 to heat the substrate 10 from the back side of the substrate, and a thermostatic chamber 123 for maintaining the constant temperature of the water. That is, the CBD apparatus 100 includes a mechanism (the reaction solution temperature control unit 110) for controlling the reaction solution temperature introduced into the CBD apparatus at a predetermined temperature separately (independently) from a mechanism (the substrate heating control unit 120) for heating the back side of the substrate, so that the reaction solution temperature and the substrate temperature can be controlled independently from each other.

In Example 2-2, the substrate II was set on the substrate holder and heated to 90° C. 15 minutes after the start of heating of the substrate II, the reaction solution with the temperature thereof controlled to 40° C. was poured into the reaction vessel, and deposition of the buffer layer was conducted for 30 minutes.

### Example 2-3

The same CBD apparatus as that used in Example 2-2 was used.

Deposition of the buffer layer was conducted in the same manner as in Example 2-2 except that the controlled temperature of the reaction solution T₂ was 20° C. and the deposition time was 120 minutes.

### Comparative Example 2-1

The same CBD apparatus as that used in Example 2-1 was used, except that the heater for heating the substrate was not used.

The substrate II without being heated was immersed in the reaction solution with the temperature controlled to 90° C., and deposition of the buffer layer was conducted for 60 minutes.

### Comparative Example 2-2

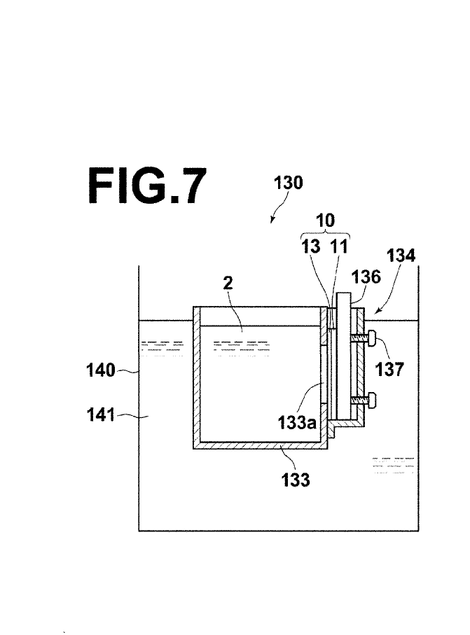

In Comparative Example 2-2, a reaction pot 130 as schematically shown in FIG. 7 was used. The reaction pot 130 includes: a reaction vessel 133, which can contain the reaction solution 2; an opening 133a which is formed in the wall of the reaction vessel 133 and is smaller than the size of the substrate; and a substrate holding section (substrate holder) 134 for holding the substrate 10 on the outer side wall surface of the reaction vessel 133 at a position corresponding to the opening 133a, such that the entire opening 133a is covered with the substrate 10. The substrate holder 134 includes a back plate 136 that can uniformly press the entire back side of the substrate 10, and a screw member 137 that can press the back plate 136 toward the opening 133a.

In a state where the reaction vessel 133 contained the reaction solution 2 and the substrate 10 was held on the substrate holder 134, the reaction pot 130 was immersed in constant-temperature water 141 in a thermostatic chamber 140 to heat the entire reaction pot 130 to 90° C., and deposition of the buffer layer was conducted for 60 minutes. In this method, the reaction solution and the substrate were heated to almost the same temperature at the same time.

### Comparative Example 2-3

In Comparative Example 2-3, the prepared reaction solution 2 was poured into a SUS reaction vessel 150, as schematically shown in FIG. 6. Then, in a state where the substrate I (substrate 10) was leaned against the inner wall of the reaction vessel with the surface on which the film was to be deposited facing down, the reaction vessel 150 was immersed in the constant-temperature water 156 in the thermostatic chamber 155, and deposition of the buffer layer was conducted for 60 minutes. In this method, the substrate I was heated via the reaction solution.

### Comparative Example 2-4

The same CBD apparatus as in Example 2-1 was used.

Deposition of the buffer layer was conducted under the same conditions as in Example 2-1 except that the controlled temperature of the reaction solution T₂ was 90° C., and the substrate heating temperature and the control temperature were the same temperature.

### Comparative Example 2-5

The same CBD apparatus as in Example 2-1 was used.

Deposition of the buffer layer was conducted under the same conditions as in Example 2-1 except that the heating of the substrate was started after the substrate was immersed in the reaction solution.

### Comparative Example 2-6

The same CBD apparatus as in Example 2-2 was used.

The substrate II was set on the substrate holder and heated to 40° C. At the same time, the reaction solution with the temperature thereof controlled to 40° C. was poured into the reaction vessel, and deposition of the buffer layer was conducted for 30 minutes. The heating of the substrate holding section was started at the same time when the substrate was immersed in the reaction solution.

### Evaluation of Film Thickness

In order to evaluate the film thickness of each buffer layer covering the GIGS layer, cross sections of the buffer layer were exposed by focused ion beam (FIB) machining after a protective film was formed on the surface of the buffer layer, and SEM observation of the cross section was conducted. From these cross sectional SEM images, the film thickness was measured at total of 35 points and an average of the measurements was calculated, as shown in Table 2.

### Evaluation of Film Surface

Presence of aggregations of particles having a primary particle size on the order of several tens to several hundreds nanometers adhering to the film surface (aggregations found when the film surface was observed from right above) in a field of view of 100 μm×100 μm was evaluated according to the following criteria, and the results are shown in Table 2.

Good (A): The number of aggregations having an equivalent circle diameter of 3 μm or more was at most three.
Acceptable (B): The number of aggregations having an equivalent circle diameter of 3 μm or more was in the range from 4 to 10.
Bad (C): The number of aggregations having an equivalent circle diameter of 3 μm or more was 11 or more.

### Transmittance of Reaction Solution

The transmittance of the reaction solution after the reaction was measured in a wavelength range from 200 nm to 800 nm. The value of transmittance at the wavelength of 550 nm is shown in Table 2.

TABLE 2

| | | | | Comparative | Comparative | Comparative | Comparative | Comparative | Comparative |
|---|---|---|---|---|---|---|---|---|---|
| | Example 2-1 | Example 2-2 | Example 2-3 | Example 2-1 | Example 2-2 | Example 2-3 | Example 2-4 | Example 2-5 | Example 2-6 |
| Substrate | Substrate I | Substrate II | Substrate II | Substrate I | Substrate I | Substrate I | Substrate I | Substrate I | Substrate II |
| Substrate | 90 | 90 | 90 | Not heated | 90 | Not heated | 90 | 90 | 40 |
| heating | | | | | | | | | |
| temperature | | | | | | | | | |
| T₁ [° C.] | | | | | | | | | |
| Start of heating | 15 minutes | 15 minutes | 15 minutes | — | At the same | — | 15 minutes | After | At the same |
| of substrate | before | before | before | | time as start | | before | immersion in | time as start |
| holding section | immersion in | immersion in | immersion in | | of heating of | | immersion in | reaction | of heating of |
| | reaction | reaction | reaction | | reaction | | reaction | solution | reaction |
| | solution | solution | solution | | solution | | solution | | solution |
| Controlled | 40 | 40 | 20 | 90 | 90 | 90 | 90 | 40 | 40 |
| temperature of | | | | | | | | | |
| reaction | | | | | | | | | |
| solution T₂ [° C.] | | | | | | | | | |
| Film formation | 30 min | 30 min | 120 min | 60 min | 60 min | 60 min | 30 min | 30 min | 30 min |
| time | | | | | | | | | |
| Film thickness | 20 | 27 | 21 | 48 | 39 | 45 | 42 | 11 | 0 |
| [nm] | | | | | | | | | |
| Deposition rate | 0.7 | 0.9 | 0.2 | 0.8 | 0.7 | 0.8 | 1.4 | 0.4 | — |
| [nm/min] | | | | | | | | | |
| Evaluation of | A | A | A | C | C | C | B | A | — |
| number of | | | | | | | | | |
| adhering | | | | | | | | | |
| particles | | | | | | | | | |
| Transmittance | 86.4 | 84.9 | 98.1 | 2.3 | 1.6 | 2.9 | 3.4 | 89.2 | 93.6 |
| of reaction solution | | | | | | | | | |
| after film | | | | | | | | | |
| formation [%] | | | | | | | | | |

As can be seen from Table 2, in Examples 2-1 to 2-3 and Comparative Example 2-5, where the reaction solution temperature was set lower than the substrate temperature, good films with a very small number of adhering particles (colloid) were obtained. Further, the transmittance of the reaction solution was 80% or more in all the Examples 2-1 to 2-3 and Comparative Example 2-5, and this clearly means that the formation of particles (colloid) was suppressed.

In Example 2-3, where the controlled temperature of the reaction solution was 20° C., the transmittance of the reaction solution after the film formation, i.e., the effect of suppressing the formation of particles (colloid), was remarkably higher than that in Examples 2-1 and 2-2, where the controlled temperature of the reaction solution was 40° C., whereas the deposition rate in Example 2-3 was lower than that in Examples 2-1 and 2-2.

On the other hand, in Examples 2-1, 2-2 and Comparative Example 2-5, where the conditions of the substrate heating temperature and the controlled temperature of the reaction solution were the same, the deposition rate largely differed between the Examples and the Comparative Example. It can be seen from this result that heating the substrate before immersion in the reaction solution significantly increases the deposition rate. In Comparative Example 2-6, where both the substrate temperature and the reaction temperature were 40° C., no film was deposited.

What is claimed is:

1. A chemical bath deposition apparatus comprising:
a reaction vessel for containing a reaction solution for chemical bath deposition to form a film on a surface of a substrate;
a substrate holding section for holding the substrate such that at least the surface of the substrate contacts the reaction solution, the substrate holding section including a fixing surface made of stainless steel or titanium on which a back side of the substrate is closely fixed;
a heater disposed at a rear side of the fixing surface, the heater heating the substrate from the back side of the substrate; and
a reaction solution temperature control unit for controlling temperature of the reaction solution in the reaction vessel.

2. The chemical bath deposition apparatus as claimed in claim 1, wherein the heater is a sheet heater disposed across an area larger than an area of the fixing surface where the substrate is fixed.

3. The chemical bath deposition apparatus as claimed in claim 2, wherein the heater is a rubber heater.

4. The chemical bath deposition apparatus as claimed in claim 1, wherein the substrate holding section holds the substrate such the surface of the substrate is oriented in a vertically downward direction.

5. The chemical bath deposition apparatus as claimed in claim 4, wherein the fixing surface of the substrate holding section is a semi-cylindrical surface.

6. The chemical bath deposition apparatus as claimed in claim 1, wherein the substrate holding section holds the substrate such that the surface of the substrate is inclined from a vertically downward direction.

7. The chemical bath deposition apparatus as claimed in claim 1, wherein the substrate holding section holds the substrate parallel to a side wall surface of the reaction vessel.

8. The chemical bath deposition apparatus as claimed in claim 1, wherein the substrate holding section comprises an end face protective member for preventing a side end face of the substrate fixed on the fixing surface from contacting the reaction solution.

9. The chemical bath deposition apparatus as claimed in claim 1, wherein at least an area of an inner wall of the reaction vessel contacting the reaction solution is coated with a hydrophobic material.

10. A method of forming a buffer layer of a photoelectric conversion device having a layered structure formed on a substrate, the layered structure including a lower electrode, a photoelectric conversion semiconductor layer, the buffer layer and a transparent conductive layer,
the method using an apparatus comprising: a reaction vessel containing a reaction solution for chemical bath deposition to form the buffer layer; a substrate holding section for holding the substrate having the photoelectric conversion semiconductor layer formed thereon such that at least a surface of the photoelectric conversion semiconductor layer contacts the reaction solution; a heater for heating the substrate; and a reaction solution temperature control unit for controlling temperature of the reaction solution,
the method comprising:
mounting the substrate having the photoelectric conversion semiconductor layer forming an outermost surface thereof on the substrate holding section;
heating the substrate by the heater to a temperature T₁ [° C.];
starting formation of the buffer layer by bringing at least the surface of the photoelectric conversion semiconductor layer into contact with the reaction solution, the temperature of the reaction solution being controlled to a temperature T₂ [° C.] lower than the temperature T₁, while the substrate is kept heated; and
maintaining the substrate at the temperature T₁ and the reaction solution at the temperature T₂ during formation of the buffer layer.

11. The method of forming a buffer layer as claimed in claim 10, wherein
the buffer layer is a Zn compound layer, and
the temperatures T₁ [° C.] and T₂ [° C.] satisfy the relationship below:
T₁≧70≧T₂+30.

12. A method of manufacturing a photoelectric conversion device having a layered structure formed on a substrate, the layered structure including a lower electrode, a photoelectric conversion semiconductor layer, a buffer layer and a transparent conductive layer, the method comprising:
forming the buffer layer by the method of forming a buffer layer as claimed in claim 10.

13. A method of manufacturing a photoelectric conversion device having a layered structure formed on a substrate, the layered structure including a lower electrode, a photoelectric conversion semiconductor layer, a buffer layer and a transparent conductive layer, the method comprising:
forming the buffer layer by the method of forming a buffer layer as claimed in claim 11.
